(19) United States
(12) Patent Application Publication
(10) Pub. No.: US 2010/0321003 A1
(43) Pub. Date: Dec. 23, 2010

(54) METER-MOUNTED EXTENDER

(76) Inventors: Franklin Christiaan Geiger, North Vancouver (CA); Mark Fairburn, North Vancouver (CA); Keith Richard Martin, Burnaby (CA); Mohammad Tootoonian Mashad, Vancouver (CA)

Correspondence Address: TANTALUS SYSTEMS CORP., #301 - 3480 GILMORE WAY, BURNABY - BRITISH COLUMBIA, V5G 4Y1, CA

(21) Appl. No.: 12/822,175

(22) Filed: Jun. 23, 2010

Related U.S. Application Data
(63) Continuation-in-part of application No. 12/457,828, filed on Jun. 23, 2009.

(51) Int. Cl. G01R 15/18

(52) U.S. Cl. 324/127

(57) ABSTRACT

A method of designing a meter-mounted extender with a transformer is disclosed, wherein losses from primary and secondary windings are equalized for a given secondary load.

### CROSS-REFERENCE TO RELATED APPLICATION

This is a continuation-in-part application of application Ser. No. 12/457,828, filed on Jun. 23, 2009, the entirety of which is hereby incorporated by reference herein and made a part of this specification.

### FIELD OF THE INVENTION

This invention relates to adapters to meters that, among other capabilities, measure common resources, especially electrical energy.

### BACKGROUND OF THE INVENTION

There are meters that, among other capabilities, measure common resources (herein, meant to include consumption of commodities like electrical energy, water, and gas). Standard meters, as understood in the electrical utilities business in the United States, Canada and herein, are those that conform to ANSI standard C12.10. This standard and others (and counterparts in jurisdictions around the world) dictate a host of restrictions, including the physical envelope or form factor, the dimensions, locations and materials for power pins, the permissible types of electrical connections with the meter, and similar items, for a one or multi-phase electricity measuring meter. These standards try to maximize safety and inter-compatibility of meters from different manufacturers. This ANSI standard in effect, prohibits or strongly discourages any electrical connection between the meter and anything else except for the power pins and grounds.

To make a standard meter a useful part of a network, it is desirable to provide it with extra functionality and ideally, to so provide by means of an easily releasably attachable adapter, and in particular herein, a collar with superior (mechanical and electrical) interconnection and safety (e.g. fuse) capabilities. It is also desirable to minimize the overall physical “footprint” of the collar (while still conforming to safety standards) and yet be large enough to house the desired extra functionality. The present invention addresses those objectives. And although the embodiment of the present invention described below is with reference to a standard electrical meter, certain aspects of it are not thereby restricted thereto, and are applicable to meters that measure other resources (such as water and gas).

The current art has complexities and associated disadvantages. Typical is U.S. Pat. No. 5,762,522 that shows a fuse and mechanical contact clip which is complex (in requiring a plurality of parts, including rivets and several angled portions). The present invention addresses the complexities with a simpler approach.

For a metered premise (house or commercial/industrial venue), the branch circuits and associated safety management (e.g. fuses) are conventionally on the load side of the meter (i.e. the part of the meter that is associated with the load side terminals, and which the utility uses to measure consumption or other attribute of electricity by the load side circuit, and is governed by a utilities regulatory regime, as distinct from a safety standards regime). Thus, for example, fuse/circuit breaker panels (and associated branch circuits to various in-house loads) are found typically inside the house and are (at least) electrically downstream from the line side of the meter, i.e. they tap the load side terminals.

For evolving applications and needs (e.g. for “smart grid” meters, as exemplified in U.S. Pat. No. 7,019,666), there are advantages to create and supply “branch circuits” on the line side of the meter (i.e. the part of the meter that is associated with the line side terminals, and that is not measured by the utility for consumption of electricity, and is governed by a safety and related regulatory regime (like the National Electric Code or equivalent), as distinct from a utilities regulatory regime).

Previous attempts (for examples, U.S. Pat. Nos. 7,182,632 and 7,040,920) promised added functionality to the meter collar using the line side of the meter without address the consequent issues. For such extra functionality, the present invention addresses such issues, including those related to safety.

### SUMMARY OF THE INVENTION

Although counter to the conventional approach of the average skilled person in transformer design, the present invention suggests to such person, to sacrifice some transformer efficiency (e.g. by inherently limiting the current) to meet space and safety constraints. Although some inefficiency results (for example, perhaps greater total I²R losses and core losses of the transformer), the “hot spot” or “hotter spots” can be reduced in maximum severity. The present invention also teaches to approximately equalize the I²R losses of the primary and secondary windings, or perhaps set a simple ratio relationship between them, and discloses the method by which to achieve approximate equality.

### BRIEF DESCRIPTION OF THE DRAWINGS

A better understanding of the present invention can be obtained when the following detailed description of the preferred embodiment is considered in conjunction with the following drawings, in which:

FIG. 1 is a perspective view of the collar in relationship with the meter and meter socket;

FIG. 2 is a detailed perspective view of the collar;

FIG. 3 is a partially broken back perspective view of the branch fuse in the collar;

FIG. 4 is a partially broken front perspective view of the branch fuse in the collar;

FIG. 5 is a back perspective view of the power pin and branch fuse;

FIG. 6 is a more detailed side of the jaw portion of FIG. 5;

FIG. 7 is a perspective view of the ring spring;

FIG. 8 is a diagram of the forces on the jaw finger on installation;

FIG. 9 is a graph of a model curve for the jaw finger;

FIG. 10 shows a perspective view of the interior of the collar;

FIG. 11 shows a front perspective view of the extender engaged within the collar;

FIG. 12 shows a cut-away side view of the extender engaged within the collar;

FIGS. 13(a), 13(b) and 13(c) show views of the components that are assembled into the extender;

FIG. 14(a) shows a back perspective view of the interior of bottom access cover of the extender;

FIG. 14(b) shows a front perspective view of the exterior of bottom access cover of the extender;

FIG. 15 shows a back perspective view of the extender arcuate portion engaged within the collar;

FIG. 16 shows a cut-away side view of the extender engaged within the collar;

FIGS. 17(a) and 17(b) show perspective views of a transformer assembly of windings, bobbins and bobbin holder; and

FIG. 17(c) shows an alternative transformer configuration to that of FIGS. 17(a) and 17(b).

### DETAILED DESCRIPTION OF THE PREFERRED EMBODIMENT

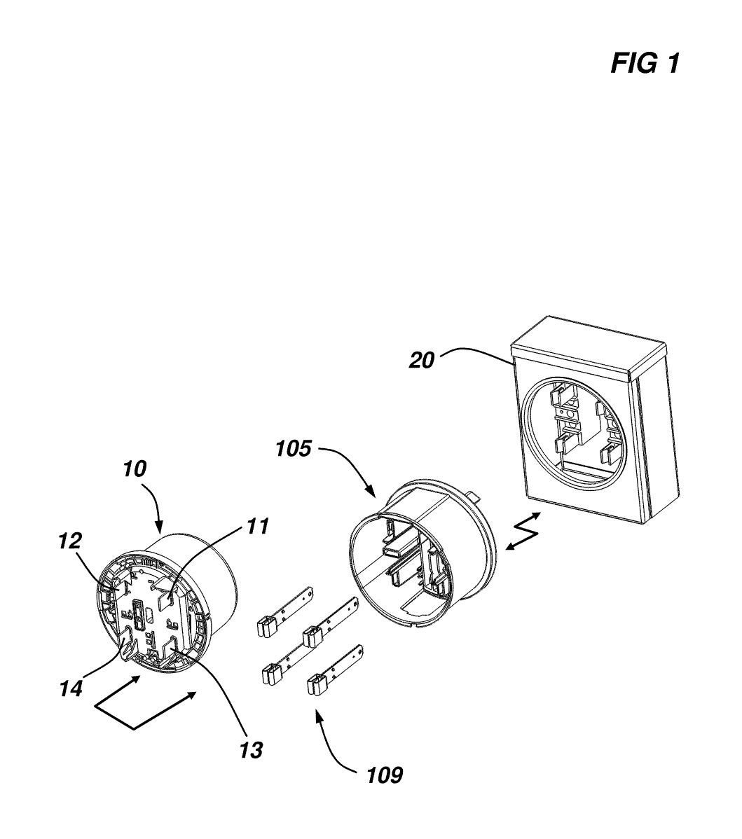

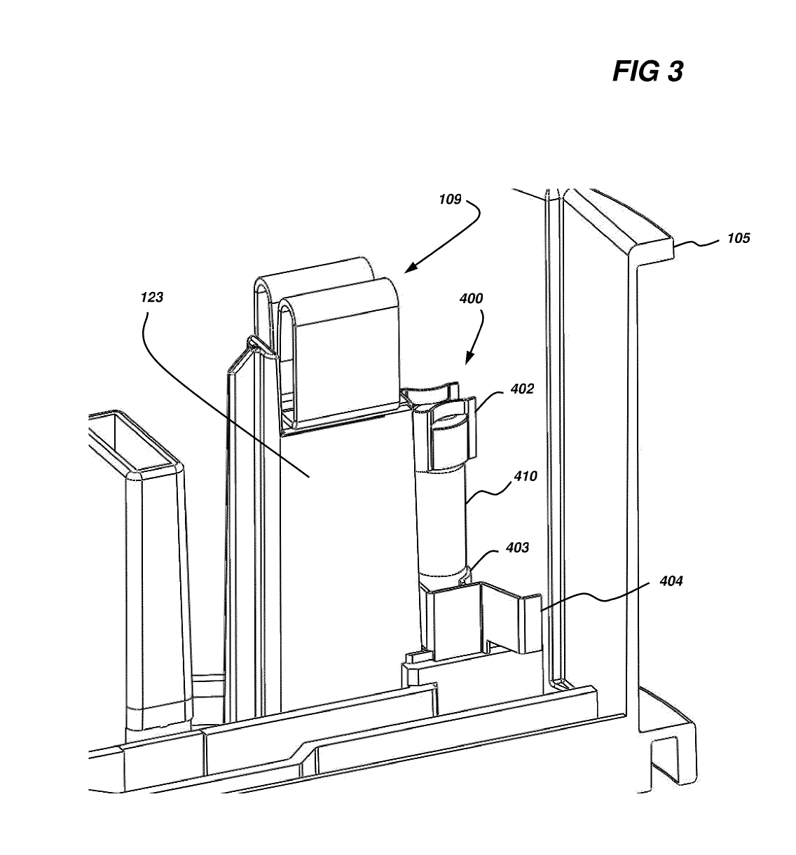

As shown in FIGS. 1-5, collar 105 is interposed (mechanically and electrically) between utility meter 10 and its associated meter socket 20.

The mechanical interposition is achieved partially by conventional mechanisms (including fastening mechanisms and mating of respective perimeter profiles and mounting surfaces) and partially by improved mechanisms (described below). The electrical agency between meter 10 and meter socket 20 is provided by the use of four identical power pins 109, snugly fitted into collar mounting slots 121 and 122 (for the meter load line terminals) and into collar mounting slots 123 and 124 (for the meter line side terminals).

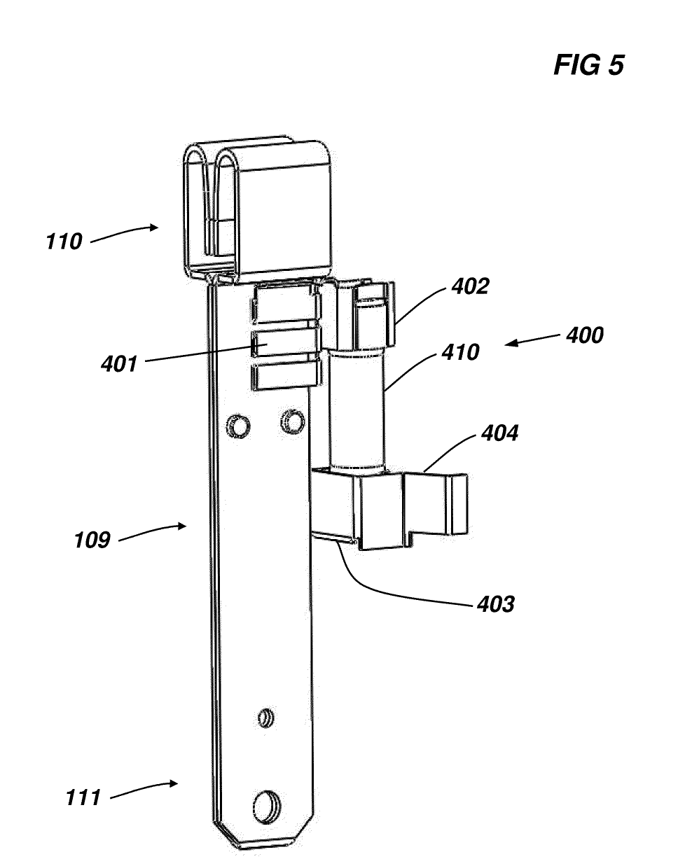

As shown in FIG. 5, attached to power pin 109 (for a line side terminal), is branch fuse holder 400 that fixedly holds fuse 410. Holder 400 has conductive friction grips 401 to attach (electrically and mechanically) holder 400 to power pin 109 associated with a line side terminal; first and second fuse holder brackets 402 and 403 that releasably hold fuse 410 by conventional snap spring mechanisms; and electric terminal 404 depending from second bracket 403 and intended for electric connection to a load circuit (being a branch load or circuit on the meter line side, not shown). Fuse 410 is in electrical parallel relationship with power pin 109 (for a line side terminal).

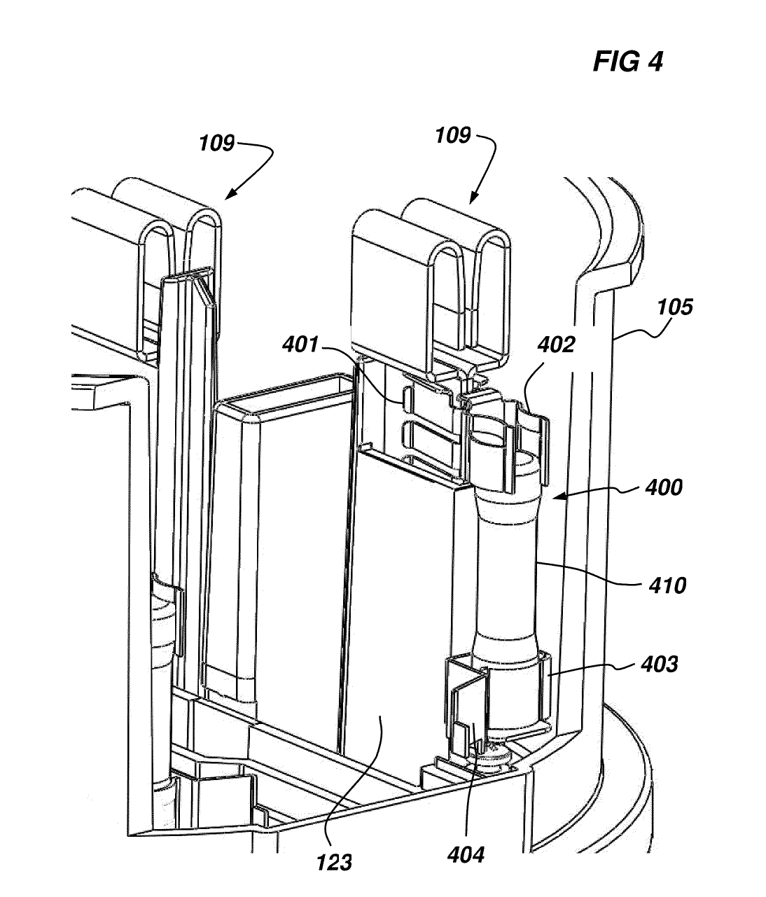

In FIG. 4, collar mounting slot 123 has been partially broken away to show branch fuse holder 400 and grips 401 partially inserted therein. The walls of slot 124 are profiled to receive grips 401 in a removably insertable relationship while providing a snug fit therewith.

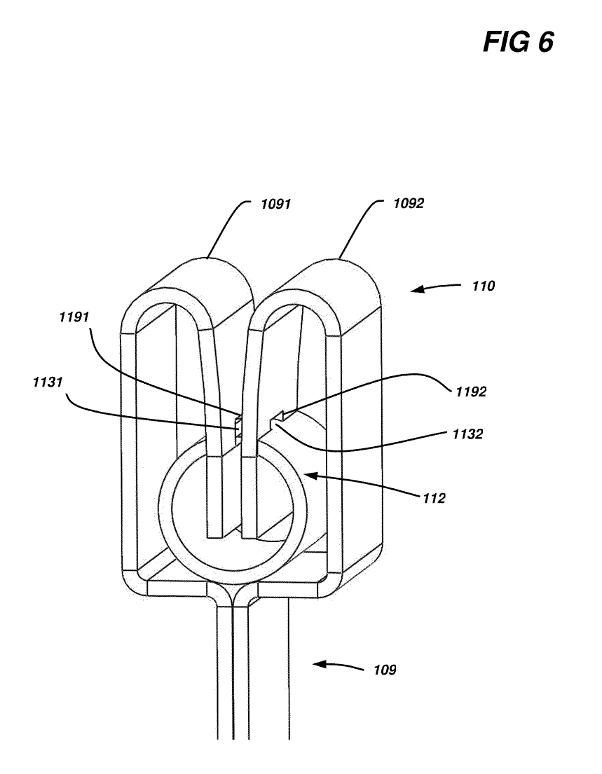

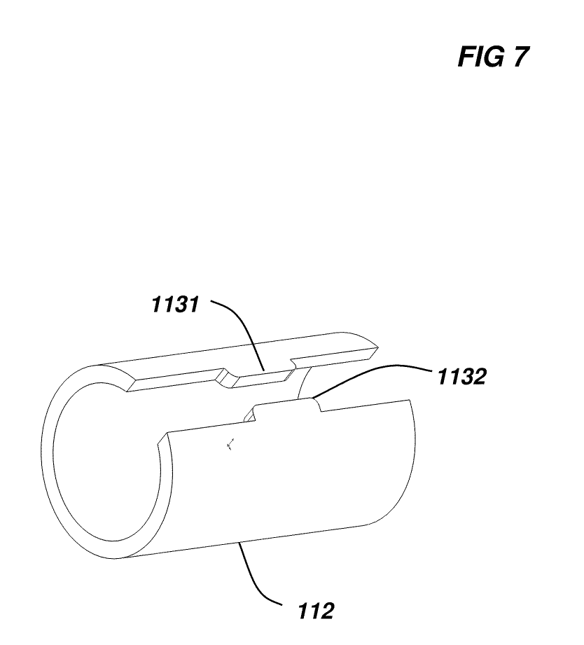

As shown in FIGS. 5-7, power pin 109 has jaw 110 and blade terminal 111. Jaw 110 includes two, opposed clips or fingers 1091 and 1092, and ring spring 112 to keep those fingers in opposition and resistant to their separation. Ring spring 112 is shown only in FIGS. 6-7 for simplicity of illustration in other drawings. Power pin fingers 1091 and 1092 are identical and are orientated in opposition as shown and are further described below.

Ring spring 112, as shown in FIGS. 6-7, has two opposed, identical protruding tabs 1131 and 1132. Jaw fingers 1091 and 1092 have respectively apertures 1141 and 1142 that respectively accepts insertion of ring spring tabs 1131 and 1132.

Once tabs 1131 and 1132 are inserted in their respective associated apertures 1141 and 1142, they remain there, and ring spring 112 then biases opposed fingers 1091 and 1092 toward each other to resist separation in the “installed state” of meter 10. (i.e. when meter 10, and in particular its meter blades 11, 12, 13 and 14, are inserted into collar 105, and in particular, its power pins 109).

In “installed state”, jaw 110 of each power pin 109 (and in particular, fingers 1091 and 1092 thereof) releasably or removably receives therebetween a meter power blade (one of blades 11, 12 associated with meter line side terminals, or one of blades 13 and 14 associated with meter load side terminals); and blade terminal 111 of each power pin 109 is inserted into the corresponding socket of meter socket 20; thereby creating electrical agency between meter 10 and meter socket 20. In “installed state”, ring spring 112 force fingers 1091 and 1092 towards each other to enhance the sandwich grip thereby on meter power blades 11, 12, 13 or 14.

When meter 10 is not inserted into collar 105 (the “uninstalled state”), although ring spring 112 contacts fingers 1091 and 1092 at tabs 1131 in apertures 1141 and 1142, they apply no or very little force on fingers 1091 and 1092.

Conventional jaws are completely planar or have a hard angle that becomes the edge of contact with the installed meter blade. In contrast, power pin jaw finger 1091 is smoothly curved. The curve is modeled on the behaviour of three locations thereof, 1091a, 1091b and 1091c, in response to the installation of meter 10 into collar 105 (i.e. the insertion of a meter blade into power pin jaw 110), as explained below.

FIG. 8 shows (but not to scale) the approximate forces acting on a collar jaw as a meter blade is inserted therein. FIG. 8 has a frame of reference for a typical application (e.g. meter 10—collar 105—meter socket 20 combination is horizontally orientated relative to the vertical outside wall of a house), where meter blade 11 is inserted horizontally from the right, leftwardly into jaw 110, and thereby creating a vertically upward displacement of jaw finger 1091 (i.e. vertical separation between jaw fingers 1091 and 1092) because the resulting force F is vertically upwards. Because of the symmetries, only finger 1091 is shown and explained below (because the force diagram for opposed finger 1092 is identical to that of finger 1091 and merely orientated vertically downward instead).

As seen in FIG. 8, location 1091a is approximately where jaw finger 1091 begins to curve and where ring spring tab 1131 is in jaw finger aperture 1141 (as explained below), i.e. is about where ring spring 112 directly acts on jaw finger 1091. Edge 1091b is the edge of contact between the leading, terminal edge of meter blade 11 and jaw finger 1091. Crest 1091c is the location representing the effective end of the curve (for modeling purposes). The curvature of finger 1091 is set by requiring a force F (created by the insertion of meter blade 11 into jaw finger 1091) to be maximum and uniform across the contact surface, acting vertically on jaw finger 1091, as seen at these three locations of jaw finger 1091, i.e. “spring location” 1091a, “leading edge” 1091b and “jaw crest” 1091c. The vertical displacement of a point on the (jaw finger model) curve (represented by “x” on the horizontal axis being the axis of insertion of meter blade 11) is modelled by force factors and vertical displacements at these three locations. Such a force F creates advantageous (mechanical and electrical) interaction between meter 10 and collar 105.

First, the vertical displacement of “spring location” 1091a (employing a rigid beam model of jaw finger 1091), is approximated by:

Δa=(F·(Lac−x)/Lac)/Ka

where x=0 corresponds to spring location 1091a; Ka=approximated effect of the (inward) remainder of jaw at 1091a represented by a spring stiffness thereat; and Lac=horizontal distance between “spring location” 1091a and “jaw crest” 1091c.

Next, the vertical displacement of “jaw crest” position 1091c is due to the force felt at that position (assuming a rigid beam model), and is approximated as:

Δc=(F·x/Lac)/Kc

where Kc=approximated effect of the (outward) remainder of jaw at 1091c represented by a spring stiffness thereat; E=modulus of elasticity of copper; and I=the area moment of the cross-section of the meter blade profile=w·t³/12, where w=width of meter blade and t=half of the thickness of the meter blade (as applicable to interaction with jaw finger 1091).

Due to these above factors, the total vertical displacement of “leading edge” position 1091b (employing a rigid beam model of jaw finger 1091), is approximated by:

Δb(rigid)=Δc·(x/Lac)+Δa·(L−x)/Lac

Next, employing an elastic beam model of jaw finger 1091 with fixed ends at 1091a and 1091c, the vertical displacement of “leading edge” 1091b is approximated as;

Δb(elastic)=(F·x²·(Lac−x)²)/(3·E·I·Lac)

Thus the total vertical displacement of “leading edge” 1091b at position (x) is

Δ(x)=Δb(rigid)+Δb(elastic).

Jaw finger 1091 is advantageously formed to have a curve in accordance with preceding formula. The preceding explanation applies identically to jaw finger 1092 and meter blades identical to meter blade 11.

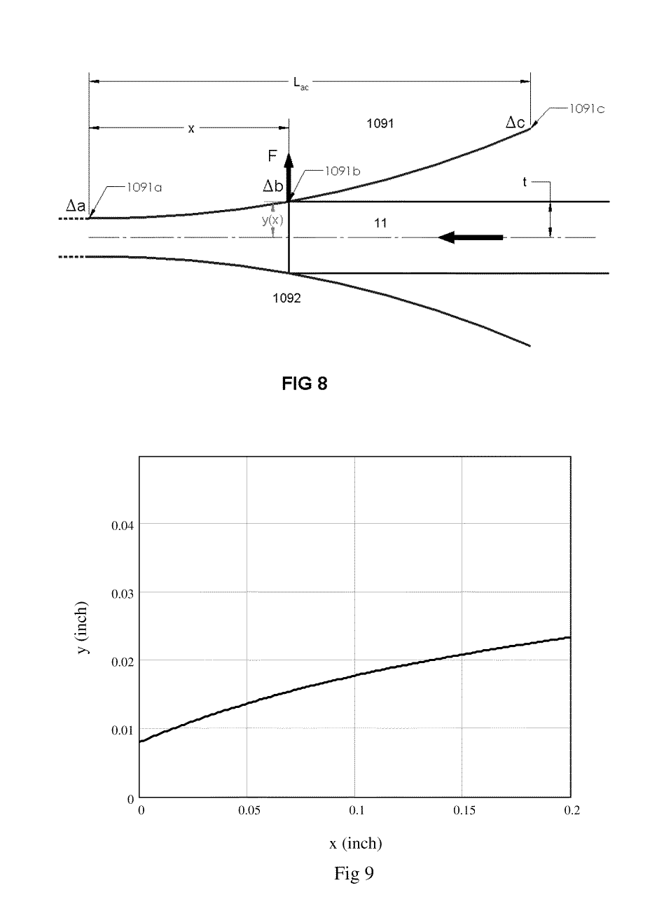

An example of the model formula is show in FIG. 9, wherein t=50 mil; w=755 mil; Ka=5Lbf/mil; Kc=3Lbf/mil.

In uninstalled state, the separation between fingers 1091 and 1092 is about 57 mils; and in installed state, the separation is in the order of 100 mils.

Examples of details of the practising of the present invention, include the following. Ring spring 112 metal is 302 or 301 stainless steel with minimum yield strength of 150000 psi. Fuse 410 is a common, high interrupt amperage capability. Power pin 109 is made of hard copper with tin plating. Fuse holder 400 is made of phosphor bronze and can be made integrally by suitable bending of a single sheet of such metal. Collar 105 may be formed of polycarbonate plastic or any other material having similar physical properties, such as those related to robustness, rigidity, temperature sensitivity, and electrical insulation. Ring spring 112 can be made of a single metal sheet of appropriate tensile and other properties, that can be cut and bent cylindrically to create opposed tabs 1131 and 1132 that are alignably insertable into corresponding apertures 1141 and 1142 of fingers 1091 and 1092 respectively.

Fingers 1091 and 1092 of power pin 109 are identical and are orientated in opposition as shown in the drawings. They may be made of a single sheet bent at the point corresponding to the jaw terminal 110 (to obviate the need of a fastener thereto). If fingers 1091 and 1092 are made discretely, they may be conventionally fastened rigidly (e.g. rivets).

Although a cylindrical ring spring 112 is disclosed, other generally C-shaped shapes are possible, each with respective advantages and disadvantages. For example, a V-shaped spring is possible.

The branch circuit may be within (entirely or partially) within collar 105 or connect to loads (i.e. devices) applicable in the factory, house or other venues. Examples of branch loads include those related to auxiliary power supply, data modem (for examples, for Internet Protocol based communications and Wide Area Networks and Local Area Networks (both wireless and wired embodiments), and external VoIP supervisory circuitry. Some branch loads may be manifested in compact form and be insertable (entirely or partially) within collar 105 and directly contact branch fuse terminal 404 (as shown). An example is the “adapter assembly” of U.S. Pat. No. 7,040,920, which may, for example, house an auxiliary backup battery pack. But also, some branch loads may be physically remote from collar 105 but electrically connected to branch fuse terminals 404.

Although branch fuse holder 400 has been shown and explained for a line side power pin, it can be used for a load line power pin, with fuse 410 appropriate for the applicable branch circuit load.

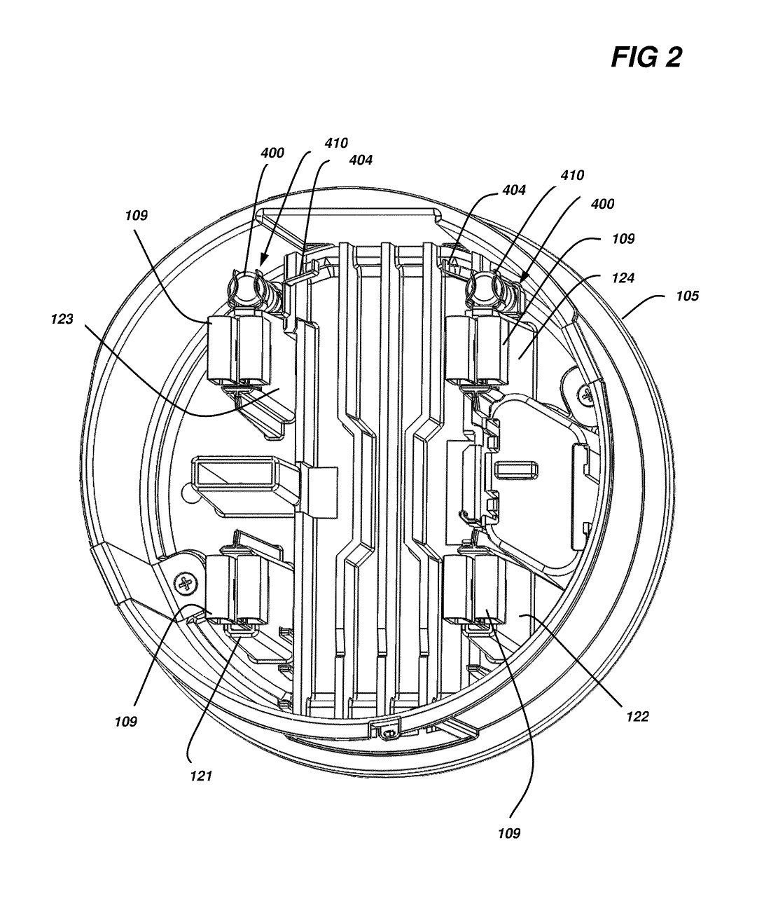

Also, although two branch fuse holders 400 have been shown, one will suffice for some applications and this invention does not require two. However, depending on the particular application and risk management concerns, the advantages of redundancy of two branch fuses are justified—in addition to redundancy, fuse 410 for both line side terminals (as shown in FIG. 2) will protect against electric faults in the power line occurring on both sides of meter 10.

Although fuse holder 400 has been shown with conductive friction grips 401 to attach (electrically and mechanically) holder 400 to power pin 109, other fuse holders and conductive attachments are contemplated as physically residing within collar 105, in particular, and electrically on the load line side of meter 10, more generally.

Although the embodiment described relates to a standard electrical power meter conforming to Form 2S, this invention is applicable to other standard meters (such as Form 3S and 4S) where only obvious modifications are necessary to accommodate a different socket/power pin arrangement. Also, it is understood by those in the art that this ANSI standard is unlikely to be modified substantially in the future but if it is modified slightly, it will be readily apparent to those in the art that this invention may be easily adjusted accordingly to fit the amended envelope or form factor. It would be a matter of simple design to accommodate different form factors (i.e. geometry of and number of sockets) and different types of meters (e.g. single-phase or multi-phase).

FIG. 1 shows a conventional (electrical-mechanical) assembly of meter 10, meter sockets 20 and intermediate collar 105.

Interface extender 200 extends the space (beyond that provided by collar 105) for housing more interface functionality. Interface functionality assists in the transfer and/or conversion of information and/or of power. An example of the former is metered data in one communications protocol (such as AINSI C12.18 and C12.19) that is converted into another protocol (such as IP protocol for Web-based applications). An example of the latter is the power transformer (for stepping down the line voltage for use in or around the home).

The interface functionality is implemented by conventional methods in the software, hardware, chemical, and mechanical arts. Examples of interface functionality include transformers, voltage regulators, temperature sensors, fibre-to-copper communication interfaces, communications protocol converters, data modem for Internet Protocol-based communications and Wide Area Networks and Local Area Networks, whether wired or wireless).

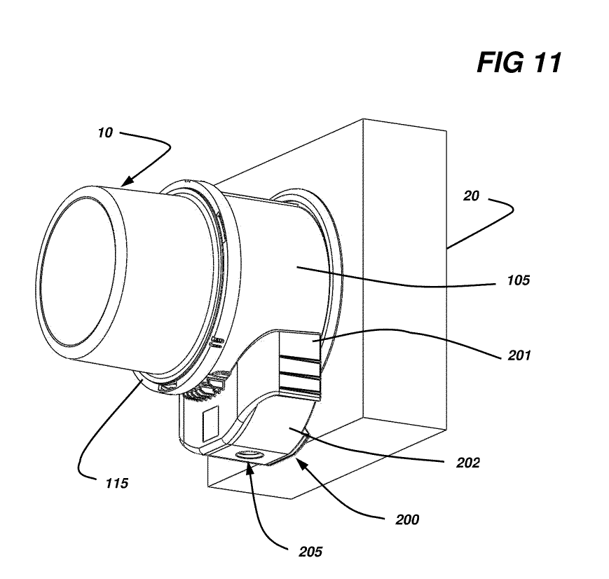

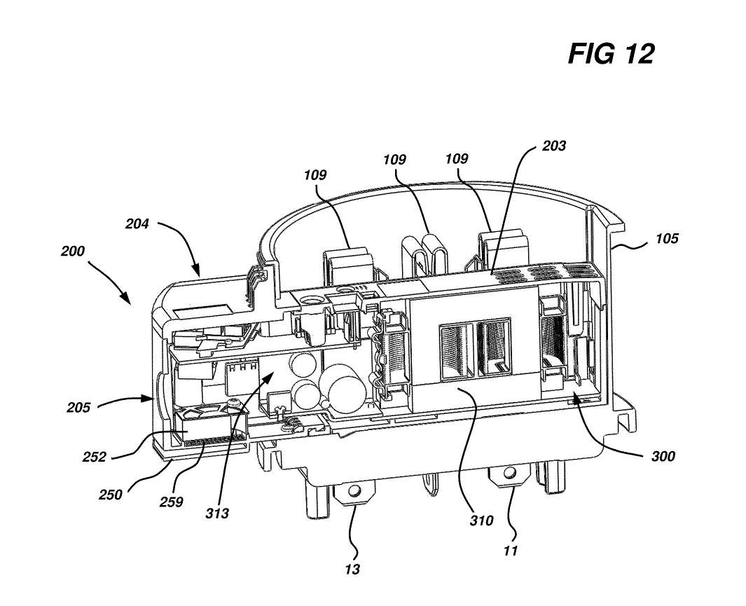

As seen in FIGS. 11 and 12, extender 200 is inserted into collar 105 through opening 100, and resides within collar 105 securely in a mechanically-electrically engaged position (by a plurality of friction-fit and snap-fit mechanisms, some of whose details are explained more below).

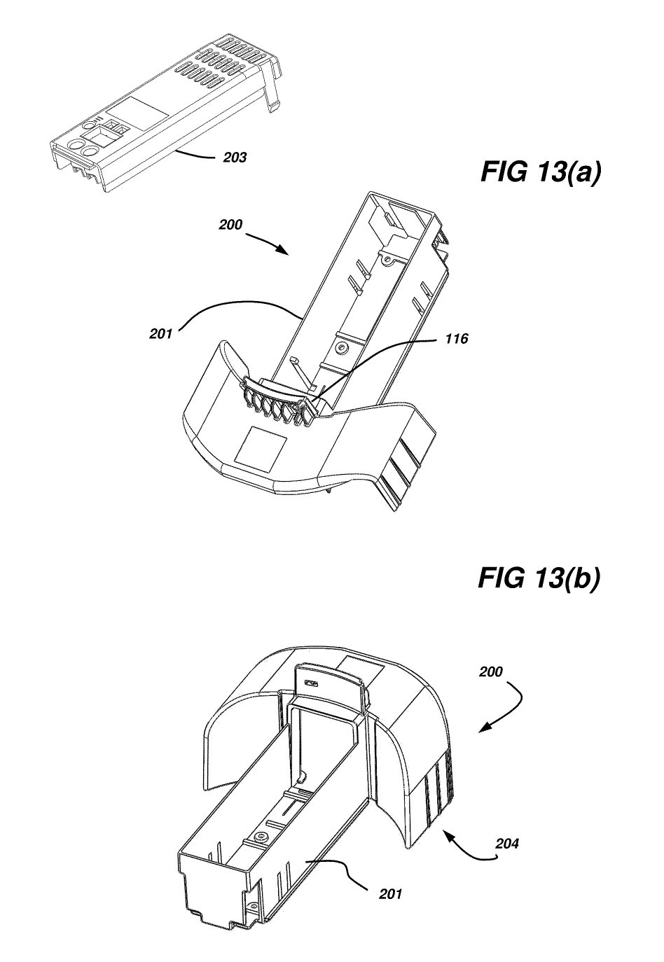

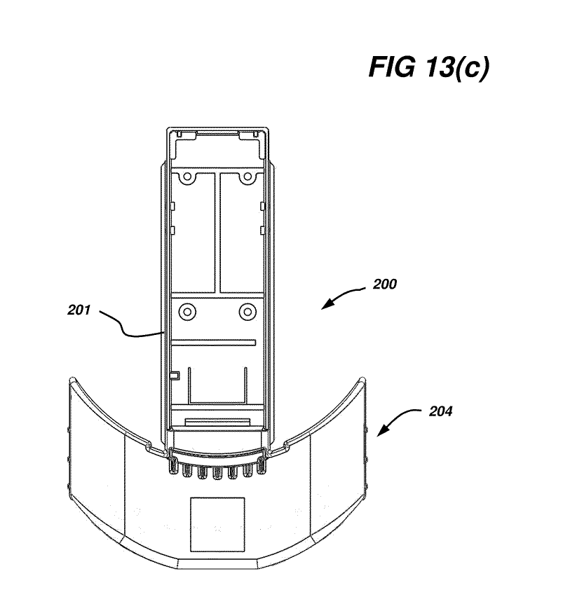

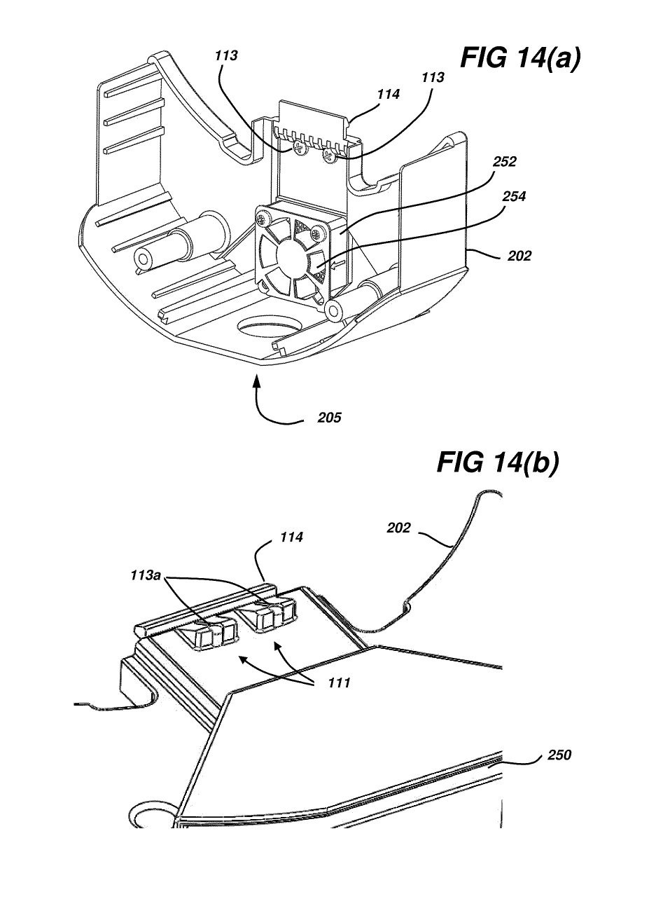

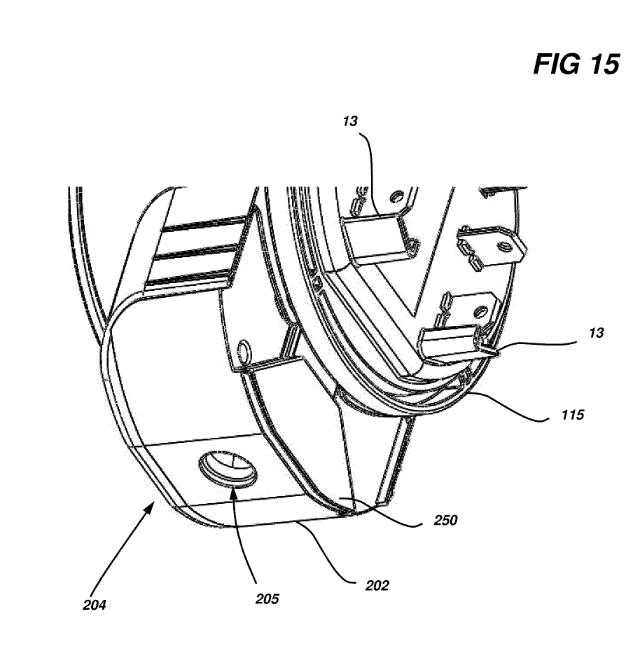

As seen in FIGS. 13-14, extender 200 has a rectangular box-like main housing 201 with bottom-back access cover 202 and top access cover 203. Covers 202 and 203 facilitate access to the contents housed by extender 200.

In the example shown in FIG. 12, there is transformer 300 and (associated or not therewith) electronics 313 (shown in idealized form). Housing 201 and access covers 202 and 203 are formed with conventional snap-fit fasteners (not shown) that cooperate for easy manual assembly into extender 200 (and disassembly thereof, as required). The housing capacity of extender 200 includes an arcuate bottom portion 204 that is visible (and accessible by removing access cover 202) even when (as seen in FIG. 11) extender 200 is inserted into collar 105 and is in its engaged position therein.

Electronics 313 may include power regulators, voltage rectifiers, control circuitry for the fan, heat sinks, temperature sensors, wireless communications transceivers, data modems, and other application-specific circuitry, whose physical footprint is compact enough to be housed in extender 200.

Like main housing body 201, arcuate portion 204 can also house interface functionality (e.g. wireless transceivers). Optionally, arcuate portion 204 has a port or knockout 205 (and related box connectors, couplings and the like) for power and communications cables and the like, for connection to remote entities (for example, a UPS (Universal Power Supply), and external VoIP supervisory circuitry, not shown).

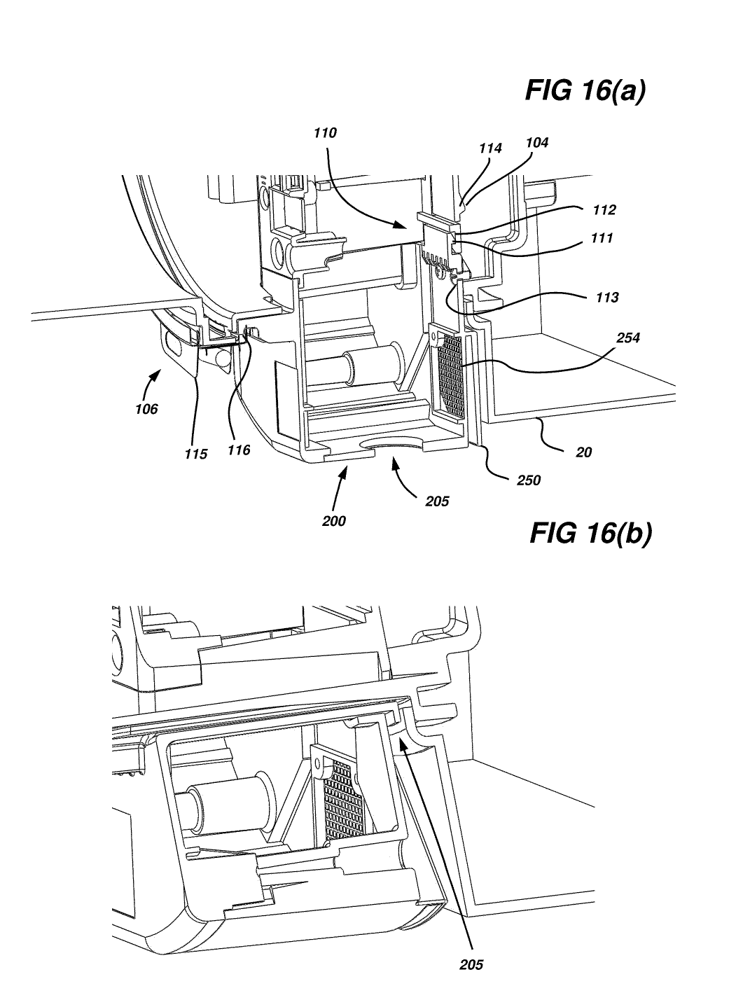

Because arcuate portion 204 is always exposed to environmental potential hazards (e.g. water, insects, dust, and human mischief), it is formed to present minimum opportunity and/or access to illegitimate or undesired intrusion/access/interference in engaged position in collar 105. For example, arcuate portion 204 presents a minimized number of, and minimized access to, openings into extender 200 (a single knockout 205 is shown as visible to the passerby while vent hood 250 (for fan 252) is “hidden” in the back). Extender 200 resides securely within collar 105 in an engaged position, as explained above, but does so in releasable way. As shown in FIG. 16 and other drawings, extender 200 is secured to collar 105 by front securing mechanisms 106 and back securing mechanisms 110 to enable extender 200 (that might house heavy interface functionality like transformer 300) to resist a pull of extender 200 trying to compel disengagement of extender 200 from collar 105. The amount of resistance may be prescribed by industry standards.

Front securing mechanism 106 includes combination of conventional lock ring 115 and an annular ledge shoulder 116 of extender 200 (as seen in FIG. 16 and other drawings). This combination provides a positive locking mechanism for ring 115 to bind extender 200 with meter 10 (which, through the strong grip of collar pins 109 and meter 10 blades 11, 12, 13 and 14, in effect binds extender 200 to meter 10 and sockets 20 through the gripping agency of the plurality of collar pins 109). This combination may be supplemented by a conventional tamper seal assembly (not shown).

Back securing mechanism 110 includes one or several snap-fit mechanisms.

As seen in FIGS. 2, 12 and 16, among others, collar 105 has internal, support ribbing/webbing 102 that has notches 104, and the back side of body 201 of extender 200 has (straight beam cantilevered) hook 114. Hook 114 and notches 104 are complementary-shaped so that they cooperate in a snap-fit relationship when extender 200 is inserted through opening 100 into collar 105.

Also, bottom-back access cover 202 (part of arcuate portion 204) has another snap-fit mechanism, as follows. FIG. 14(b) and other drawings show that access cover 202 has two pairs of wedge-shaped latches or hooks 111 that snap fit over, onto and latch against ledge 112 of collar 105. For each said pair of hooks 111, there is a metallic (or otherwise very rigid) screw 113 that is embedded into the associated portion of cover 202 and has its terminal tip 113a emerging in between or proximate said pair of hooks 111. Tip 113a is coincident with the latching face of said hooks 111 and so together, they provide an enhanced (very rigid) gripping surface hook to interact with ledge 112 in resisting disengagement. The location of latch 111/ledge 112 (as supplemented by screw tips 113a) is sufficiently proximate to a location where an ordinary, flat-head screwdriver can be easily inserted between access cover 202 and collar 105 (proximate the securing mechanism of hook 111 and ledge 112, for example point 205) to separate hook 111 from ledge 112 and then rotated slightly, to thereby slightly separate cover 202 and collar 105 sufficiently to allow hook 111 to disengage ledge 112 and thereby help release extender 200 from collar 105.

As indicated above, one advantageous interface functionality is transformer 300. A common issue with transformers are regulatory and safety concerns and requirements about their thermal output. In particular, air flow, cooling and transformer design are addressed by the present invention.

Bottom-back access cover 202 has air vent hood 250 in air-communication with fan 252 through intermediate filter grill 254 (FIG. 14 shows fan 252 and FIG. 16 does not, for simplicity of illustration). The mesh size of grill 254 is large enough so as not to impede air flow but small enough to filter against penetration by dirt and many types of insects. Vent hood 250 is relatively thin but relatively wide triangularly fan-shaped to present a 3-dimensional inlet through which to draw air in to minimize the pressure drop as air is drawn into extender 200. Vent hood 250 (as the back part of extender 200 when inserted into collar 105) is in an isolated and hard-to-access location and is not visually apparent to passersby and so presents no invitation to allure kids with a water hose and mischievous intentions.

There is conventional electronics 313 associated with fan 252 and thermistor 315 to turn on/off fan 252 (in response to monitored thermistor 315 (and/or other thermal sensors within extender 200) to draw air into extender 200 to regulate its internal temperature within desired or regulated limits. Also, there is (not shown) a conventional thermal fuse associated with secondary windings 309 and an over-current fuse immediately after transformer secondary windings 309 for any single point of failures in electronics 313 (that may have, for example, switching power supply).

The temperature within extender 200 may rise too high (and become injurious to the operation of electronics 313 and/or offensive to regulatory thermal restrictions) because of I²R losses from transformer 300.

Thermistor 315 (or resistance temperature detectors or other conventional temperature or heat sensor) is attached to (or equivalently associated with) transformer secondary windings 309. One teaching of the present invention is that by balancing or equalizing the I²R losses of transformer primary windings 308 and secondary windings 309, the single sensor 315 associated with secondary windings 309 will, in effect, quickly and accurately detect the temperature at or proximate primary windings 308 (where some regulations/jurisdictions preclude safety devices like fuses and temperature sensors). The way of balancing or equalizing the I²R losses of transformer primary windings 308 and secondary windings 309, will be explained below.

Electronics 301 may, optionally, supplement thermal regulation by providing conventional thermal regulation accessories, including (not shown) a heat sink and a second thermistor or other thermal sensor proximate secondary windings 309. The heat sink can be any black anodized aluminum surface (or similar material) in such shape as can fit within free space within extender 200 without unduly disturbing air flow therethrough.

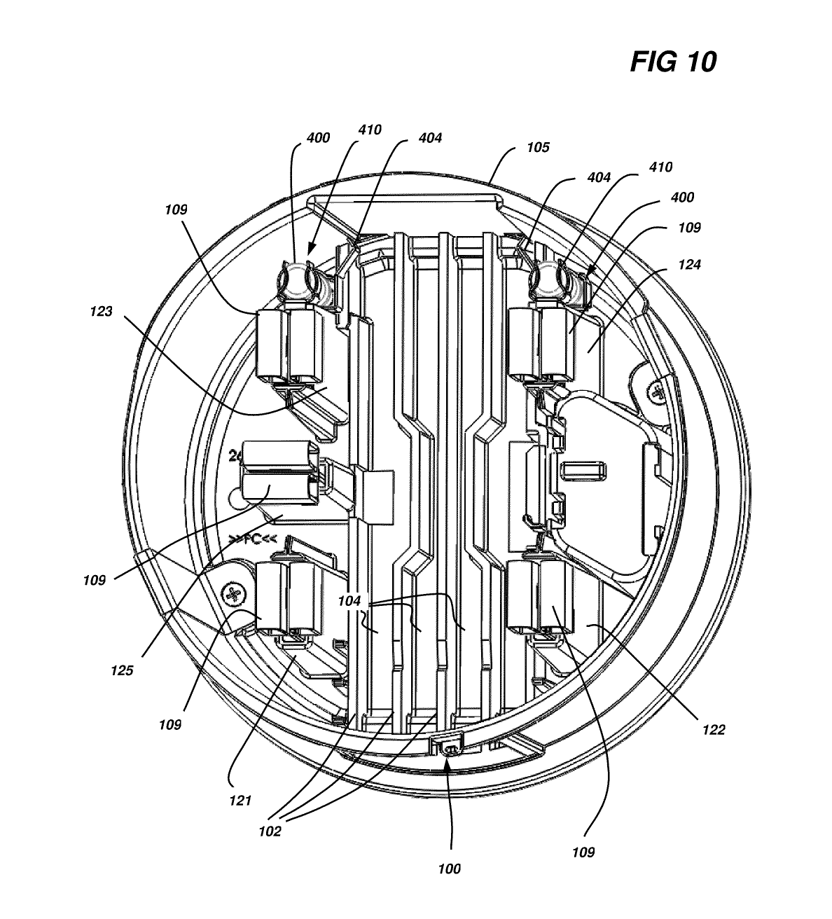

The dimensions of extender 200, and of transformer 300 housed therein, are restricted by physical-legal constraints and objectives. Examples of constraints and objectives include: the industry-standardized placement of power pins 109 (S-2, as seen in FIG. 10) and (within transformer 300) regulated separations for “bare live parts”; regulated thermal limits (not to mention the physical adverse effect of heat on any electronics. the degree of resistance against a removable meter-mounted extender being pulled out, etc. The selection of transformer design parameters is a good source of trying to get maximum utility out of extender 200 while respecting all the constraints.

For a given or maximum load on the side of secondary windings 309 (for example, a UPS that needs to be recharged from the power line), the primary and second windings 308 and 309 are each composed of the particular combination of parameters such, windings wire material, number of turns of windings and the cross-section of windings wire, so that core 310 is saturated when the secondary load is connected, and thus the transformer becomes inherently current-limiting. With the present invention's insight to saturate the core for a given secondary load and other constraints and objectives (explained above), the particular method of saturating by selecting the best combination of transformer design parameters, is within the normal skills of those in the art; and includes the determination or selection of the number of windings turns, the selection of material of core 310, the cross-section of the windings wires and the like. With core 310 in saturation, it is not difficult (by experimentation, if necessary) to select the number of turns and the cross-sections of primary and secondary windings 308 and 309, so that any expected spiked I²R “hot spot” loss on the secondary windings 309 is reduced to approximate that of I²R loss on the primary windings 308. More generally, there are three main sources of losses in transformer 300 with a given secondary load—losses from each of primary and secondary windings 308 and 309, and losses from core 310; and accordingly, it is advantageous to try to reduce the highest or higher sources of loss by “redistributing” the three sources of losses so as to render transformer 300 into a substantially uniform heat radiator. Although the formerly lower sources of loss will increase as a result of the “redistribution” and the overall total loss of transformer 300 might be higher as the result of “redistribution”, the extreme spikes of loss or “hot spot(s”) will be reduced and thereby advantageously address regulatory thermal requirements. And this is all achieved by putting the core into saturation to determine the best combination of core 310 material, number of turns and cross-section for primary and secondary windings 308 and 309 to “even out” the three heat loss sources.

It is advantageous (but not necessary) to select a core material that has properties of maximum flux transfer between primary and secondary windings (in the “normal” range of operation) and then to determine, for example, the number of turns, while respecting all other constraints. But it may be that some of the other constraints affect the choice of core material and dictate some loss of flux transfer.

One advantage of being inherently current-limiting is that no extra external safety devices are needed for primary windings side (which some jurisdictions/standards require).

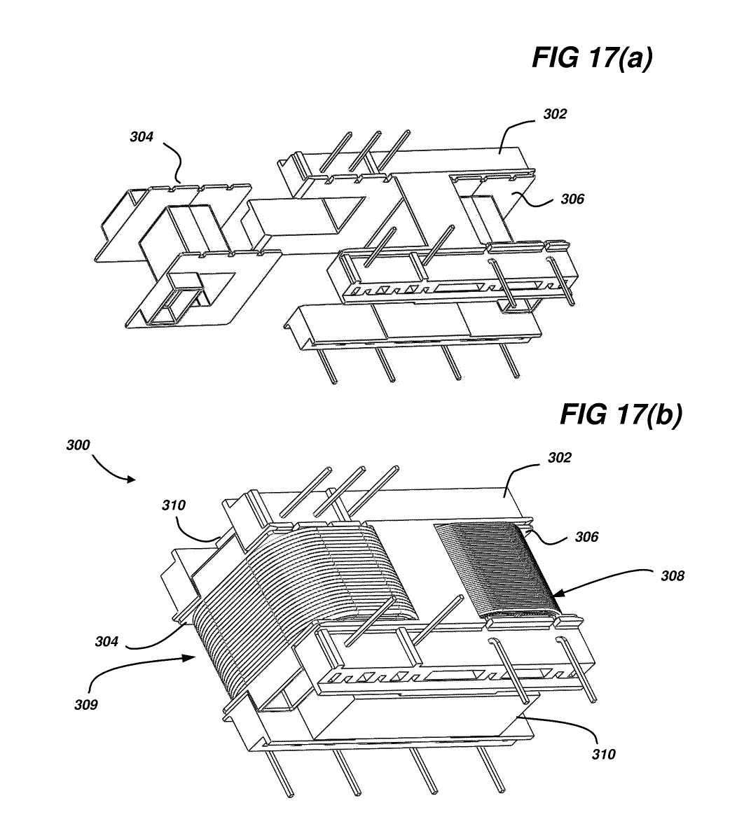

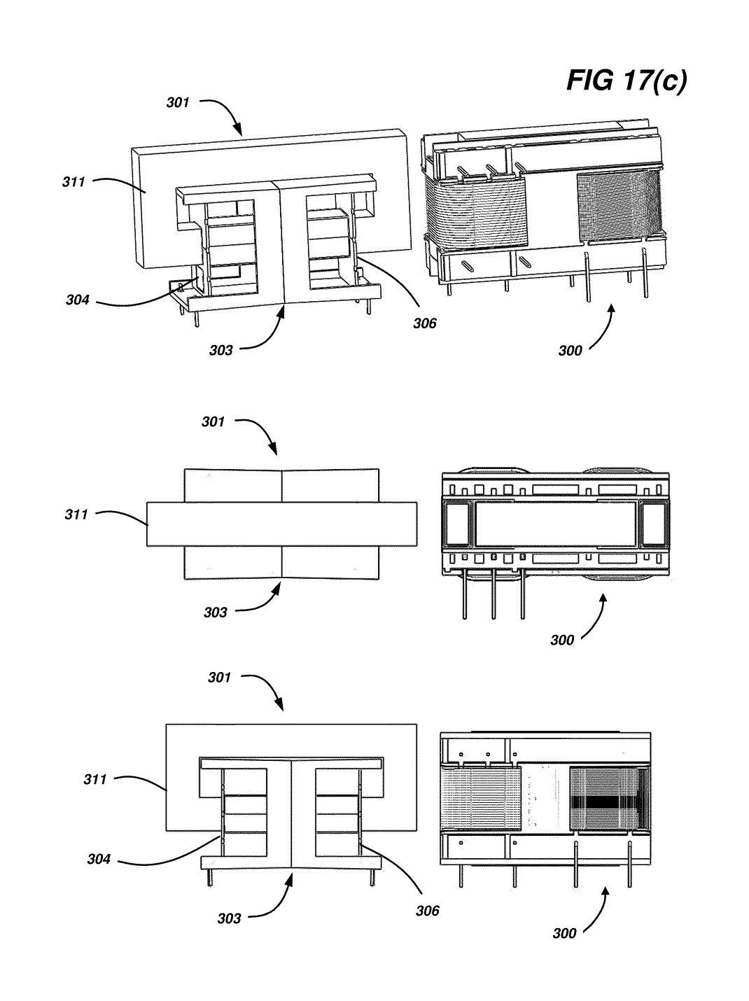

FIGS. 17(a) and 17(b) shows transformer 300 assembled from bobbin holder 302 holding primary bobbin 304 and secondary bobbin 306 around which are respectively primary windings 308 and secondary windings 309, in interactive combination with U-I core 310.

The dimensions of the bobbin holder 302 and the flange walls of bobbins 304 and 306 are such to satisfy regulatory requirements related to spacings between bare live parts of opposite polarity. For example, separations for over-the-air and over-surface creepage may be required to be at least 9.5 mm and 19 mm respectively.

What is shown in FIGS. 17(a) and 17(b) is a geometry of axially separated (primary and secondary) windings areas. An alternative geometry has radially separated windings areas (secondary and primary windings) as shown in FIG. 17(c) that still respects the S-2 or 12-S power pin placements (of FIG. 10). As FIG. 17(c) shows, the 3-dimensional footprint of alternative geometry transformer 301 is very proximate to that of transformer 300. Alternative geometry transformer 301 has the primary and second windings on bobbins 304 and 306 as before, but perhaps with different bobbin holder 303 and differently dimensioned U-I core 311. The efficiency of transformer 301 may be better in some ways than transformer 300 and so the number of windings turns may be different than that of transformer 300 to achieve the same or similar thermal situation. Bobbing holder 303 may be made integrally of plastic or be made of two opposed plastic cups held together by core 311.

Commonly, transformer bobbins and related parts, are conventionally formed of a single molded plastic (e.g. FR 530) piece to act as an insulator. Primary and secondary bobbins 304 and 306 may be identical so for simplicity of explanation herein, only one will be described.

Fan 252 can be alternatively configured to draw hot air out of extender 200 but in the physical layout illustrated (where transformer 300 is located relative to electronics 313), this dynamic would unadvantageously draw hot air from transformer 300 over the electronics 313. But the (dis)advantages of a direction of fanned air flow depends on the specific interface functionality contents of extender 200 and their physical layout, the air flow paths, and the like, and so configuring the direction of air flow is a simple matter of simple design choice.

Although extender 200 is shown as an assembly of three parts (main body 201 with two access covers 202 and 203), for some applications, only one or no access covers would suffice. Although a removable extender is shown, it need not be removable. Conventional fasteners can be provided so that upon insertion of extender 200 into collar 105, a subsequent removal of extender 200 would require a destructive action of those fasteners or similar. Furthermore, extender 200 need not be discrete from collar 105 and can be mostly formed integrally therewith by conventional plastics technology, leaving only, for example, the bottom-back access cover 202 to be easily detachable as explained herein.

It is possible to simply circulate the air within extender 200 (i.e. draw hot air from transformer 300 and flow it over a heat sink, with no or minimal air flow egress out of extender 200 into the presumably cooler environment). Also, it is possible that the particular interface functionality housed by extender 200 can tolerate a less accurate or quick thermal regulation, in which case, a single temperature sensor (not shown) for the entire extender 200, located proximate transformer 300, would suffice. While these two preceding possibilities may not have a wide range of applications, they may still enjoy the benefits of many aspects of extender 200.

Additional objects and advantages of the invention are set forth in, or will be apparent to those of ordinary skill in the art from, the detailed description herein. Also, it should be further appreciated by those of ordinary skill in the art that modifications and variations to the specifically illustrated, referred and discussed features and steps hereof may be practiced in various embodiments and uses of this invention without departing from the spirit and scope thereof, by virtue of present reference thereto. Such variations may include, but are not limited to, substitution of equivalent means and features, materials, or steps for those shown, referenced, or discussed, and the functional, operational, or positional reversal of various parts, features, steps, or the like.

It is to be understood that different embodiments, as well as different presently preferred embodiments, of this invention may include various combinations or configurations of presently disclosed features, steps, or elements, or their equivalents (including combinations of features or steps or configurations thereof not expressly shown in the figures or stated in the detailed description).

Before any embodiments of the invention are explained in detail, it is to be understood that the invention is not limited in its application to the details of construction and the arrangement of components set forth in the following description or illustrated in the drawings. The invention is capable of other embodiments and of being practiced or of being carried out in various ways. Also, it is to be understood that the phraseology and terminology used herein is for the purpose of description and should not be regarded as limiting. The use of terms “including”, “comprising” or “having” and variations thereof is meant to encompass the items listed thereafter and equivalents thereof as well as additional items. The terms “associated”, “mounted,” “connected,” and “coupled” are used broadly and encompass both direct and indirect association, mounting, connecting, and coupling. Furthermore, “associated”, “connected” and “coupled” are not restricted to physical or mechanical associations, connections or couplings.

Items that are identified herein as “not shown” (or similar) means that they are not illustrated in the drawings only for simplicity of illustration and are, in any case, those conventional items that would be within the conventional design range of the average skilled person in the art. For example, not shown are all the conventional vents and ports for various (air, optical, electrical) inputs and outputs in extender parts like access covers 201 and 202, and body 201 which would be conventionally designed by the skilled person in response to application specific needs. Also, for simplicity of illustration, not all components are shown in all drawings. For example, ring 115 is shown in some drawings but not all.

Although the method and apparatus of the present invention has been described in connection with the preferred embodiment, it is not intended to be limited to the specific form set forth herein, but on the contrary, it is intended to cover such alternatives, modifications, and equivalents, as can be reasonably included within the spirit and scope of the invention as defined by the appended claims. All figures are drawn for ease of explanation of the basic teachings of the present invention only; the extensions of the figures with respect to number, position, relationship, and dimensions of the parts to form the preferred embodiment will be explained or will be within the skill of the art after the following teachings of the present invention have been read and understood. Further, the exact dimensions and dimensional proportions to conform to specific force, weight, strength, and similar requirements will likewise be within the skill of the art after the following teachings of the present invention have been read and understood.

1. A meter-mounted extender, comprising:
(a) a transformer with primary windings and secondary windings;
(b) a load connectable to said transformer secondary windings;
where the I²R losses of said transformer secondary windings are substantially equal to the I²R losses of said transformer primary windings for said load when connected to said transformer secondary windings.

2. The extender of claim 1, further comprising a temperature sensor associated with said transformer secondary winding.

3. The extender of claim 2, further comprising a fan and vent for moving air in and out of said extender.

4. The extender of claim 3, wherein said vent is located in a substantially inaccessible location.

5. The extender of claim 3, further comprising a vent hood to protect said hood against undesired access.

6. The extender of claim 6, wherein said with vent hood is fan shaped to minimize the pressure drop of air therethrough.

7. The extender of claim 3, further comprising control circuit to turn on and off said fan in response to said transformer secondary winding temperature sensor.

8. A method of detecting the temperature proximate the primary windings in a transformer having primary windings, secondary windings, and core, comprising the steps of:
(a) associating a thermistor to secondary windings;
(b) equalizing the I²R losses of the primary and secondary windings.

9. A method of designing a transformer having primary windings, secondary windings, and core, comprising the steps of;
(a) connecting a load to the secondary windings;
(b) saturating the core;
(c) reducing the loss of the largest loss source among core, primary and secondary windings, by changing the number of turns and cross-section of the windings, thereby rendering the transformer to be a more uniform heat loss radiator.
